(19) United States
(12) Patent Application Publication
(10) Pub. No.: US 2010/0319766 A1
(43) Pub. Date: Dec. 23, 2010

(54) SOLAR CELL AND METHOD FOR MANUFACTURING THE SAME

(75) Inventor: Dong-Chul SUH, Suwon-si (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si, (KR)

(21) Appl. No.: 12/614,828

(22) Filed: Nov. 9, 2009

(30) Foreign Application Priority Data
Jun. 17, 2009 (KR) 10-2009-0054094

(51) Int. Cl. H01L 31/00; H01L 31/18

(52) U.S. Cl. 136/256; 438/98; 257/E31.124

(57) ABSTRACT

A solar cell includes; a semiconductor substrate including a first conductive type part selected from one of a p-type and n-type material and a second conductive type part selected from p-type and n-type material different from the first conductive type part, and a plurality of contact holes penetrating from a first surface to a second surface of the semiconductor substrate, a first electrode disposed on the first surface of the semiconductor substrate and electrically connected to the second conductive type part, a second electrode disposed on the second surface of the semiconductor substrate and electrically connected to the first conductive type part, and a dielectric layer disposed between the semiconductor substrate and the second electrode in the contact hole, and a method of manufacturing the solar cell.

This application claims priority to Korean Patent Application No. 10-2009-0054094, filed on Jun. 17, 2009, and all the benefits accruing therefrom under 35 U.S.C. §119, the content of which in its entirety is herein incorporated by reference.

### BACKGROUND OF THE INVENTION

1. Field of the invention

This disclosure generally relates to a solar cell and a method for manufacturing the same.

2. Description of the Related Art

A solar cell is a photoelectric conversion device that transforms solar energy into electrical energy, and has attracted much attention as a renewable and pollution-free next generation energy source.

A solar cell typically includes p-type and n-type semiconductors and produces electrical energy by transferring electrons and holes to the n-type and p-type semiconductors, respectively, and then collecting electrons and holes in each electrode when an electron-hole pair (“EHP”) is produced by solar light energy absorbed in a photoactive layer inside the semiconductors.

Further, a goal of solar cell manufacturing is to have as high an efficiency as possible for producing electrical energy from solar energy. In order to improve this efficiency, a solar cell needs be able to effectively absorb light with less loss of energy, e.g., via thermal processes and other non-electrical conversion of the solar energy, so that such a solar cell may produce as many electron-hole pairs as possible, and then collect the produced charges without loss.

BRIEF SUMMARY OF THE INVENTION

One exemplary embodiment of the present invention provides a solar cell having improved efficiency by enhancing light absorption and decreasing loss of produced charges.

Another exemplary embodiment of the present invention provides a method of manufacturing the solar cell.

According to one exemplary embodiment of the present invention, a solar cell includes; a semiconductor substrate including a first conductive type part including one of a p-type material and an n-type material, a second conductive type part including the other of a p-type material and an n-type material different from the first conductive type part, and a plurality of contact holes which penetrate from a first surface of the semiconductor substrate to a second surface thereof, wherein the first surface and the second surface are substantially opposite to one another, a first electrode disposed on the first surface of the semiconductor substrate and electrically connected to the second conductive type part of the semiconductor substrate, a second electrode disposed on the second surface of the semiconductor substrate and electrically connected to the second conductive type part of the semiconductor substrate, and a dielectric layer disposed between the semiconductor substrate and the second electrode in the plurality of contact holes.

In one exemplary embodiment, the solar cell may further include a plurality of third electrodes disposed on a surface of the semiconductor substrate corresponding to the plurality of contact holes, respectively, wherein the plurality of third electrodes are connected to the first electrode through the plurality of contact holes.

In one exemplary embodiment, the plurality of the third electrodes may be arranged adjacent to one another along a first direction.

In one exemplary embodiment, a plurality of the plurality of contact holes may be arranged in a direction substantially perpendicular to the first direction.

In one exemplary embodiment, the solar cell may further include an insulation layer disposed between the semiconductor substrate and the first electrode.

In one exemplary embodiment, the dielectric layer may be disposed between the first conductive type part of the semiconductor substrate and the third electrode in the plurality of contact holes.

In one exemplary embodiment, the dielectric layer may also be disposed between the first conductive type part of the semiconductor substrate and the plurality of third electrodes in the plurality of contact holes.

In one exemplary embodiment, the second electrode fills at least a portion of a dielectric contact hole disposed in the dielectric layer on the second surface of the semiconductor substrate.

In one exemplary embodiment, the dielectric layer may surround the plurality of contact holes.

In one exemplary embodiment, the dielectric layer may include at least one material selected from the group consisting of Al₂O₃, AN, AlON, and a combination thereof.

In one exemplary embodiment, the contact holes may have a different diameter at the first surface of the semiconductor substrate and the second surface of the semiconductor substrate.

Accordingly, in one exemplary embodiment, the contact holes may be shaped as a truncated cone.

In one exemplary embodiment, the solar cell may further include a protective layer disposed on the dielectric layer.

According to one exemplary embodiment of the present invention, a method of manufacturing a solar cell is provided that includes; preparing a first conductive type part of a semiconductor substrate, wherein the first conductive type part is selected from one of a p-type material and an n-type material, forming a plurality of contact holes extending from a first surface of the semiconductor substrate to a second surface of the semiconductor substrate, preparing a second conductive type part, including the other of a p-type material different than the first conductive type part by supplying a part of the semiconductor substrate with impurities, disposing a dielectric layer on the second surface and a side of the semiconductor substrate corresponding to the plurality of contact holes, disposing a first electrode electrically connected to the second conductive type part of the semiconductor substrate on the first surface of the semiconductor substrate, and disposing a second electrode electrically connected to the first conductive type part of the semiconductor substrate on the second surface thereof, wherein the second electrode is separated from the first electrode.

In one exemplary embodiment, the manufacturing method of a solar cell may further include connecting a plurality of third electrodes to the first electrode on the first surface of the semiconductor substrate.

In one exemplary embodiment, at least one of forming the first electrode, the second electrode, and the plurality of third electrodes may be performed by a screen-printing method.

In one exemplary embodiment, the semiconductor substrate may include an insulation layer disposed on the first surface after supplying the second conductive part of the semiconductor substrate with impurities.

In one exemplary embodiment, the method may further include removing the first conductive type part of the semiconductor substrate on one surface and sides corresponding to the plurality of contact holes, before disposing a dielectric layer there.

In one exemplary embodiment, the second conductive type part of the semiconductor substrate on the second surface and sides corresponding to the plurality of contact holes may be removed using the insulation layer as a mask.

In one exemplary embodiment, the method may further include disposing a protective layer on the semiconductor substrate after disposing the dielectric layer on the semiconductor substrate.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a top plan view showing the front side of an exemplary embodiment of a solar cell;

FIG. 2 is a top plan view showing the rear side of an exemplary embodiment of a solar cell;

FIG. 3 is a cross-sectional view of an exemplary embodiment of a solar cell taken along line III-III of FIGS. 1 and 2;

FIGS. 4 to 11 are cross-sectional views sequentially showing an exemplary embodiment of a method of manufacturing the exemplary embodiment of a solar cell of FIGS. 1 to 3;

FIG. 12 is a cross-sectional view of another exemplary embodiment of a solar cell taken along line III-III of FIGS. 1 and 2;

FIGS. 13 to 19 are cross-sectional views sequentially showing an exemplary embodiment of a method of manufacturing the exemplary embodiment of a solar cell of FIG. 12; and

FIGS. 20 to 21 are cross-sectional views respectively showing another exemplary embodiment of a solar cell.

### DETAILED DESCRIPTION OF THE INVENTION

The invention now will be described more fully hereinafter with reference to the accompanied drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/ or “comprising,” or “includes” and/ or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

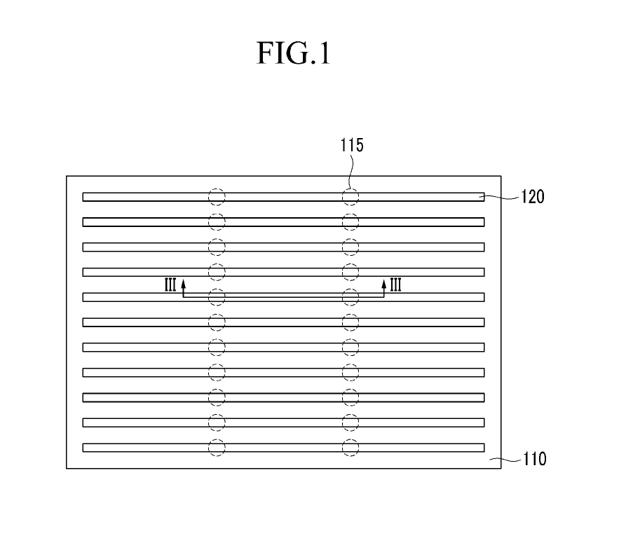

Referring to FIGS. 1 to 3, an exemplary embodiment of a solar cell is illustrated.

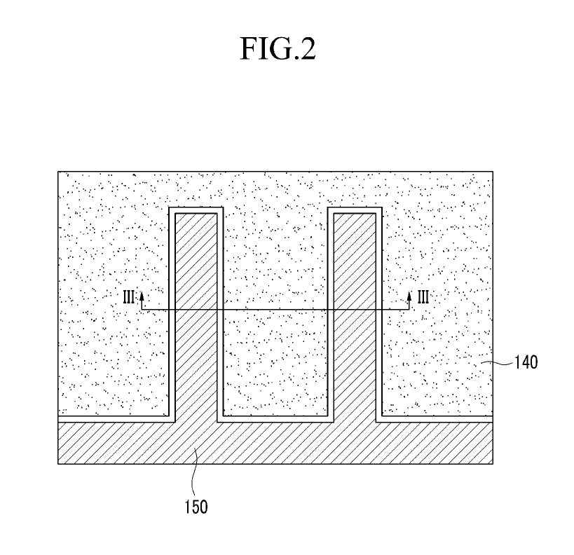

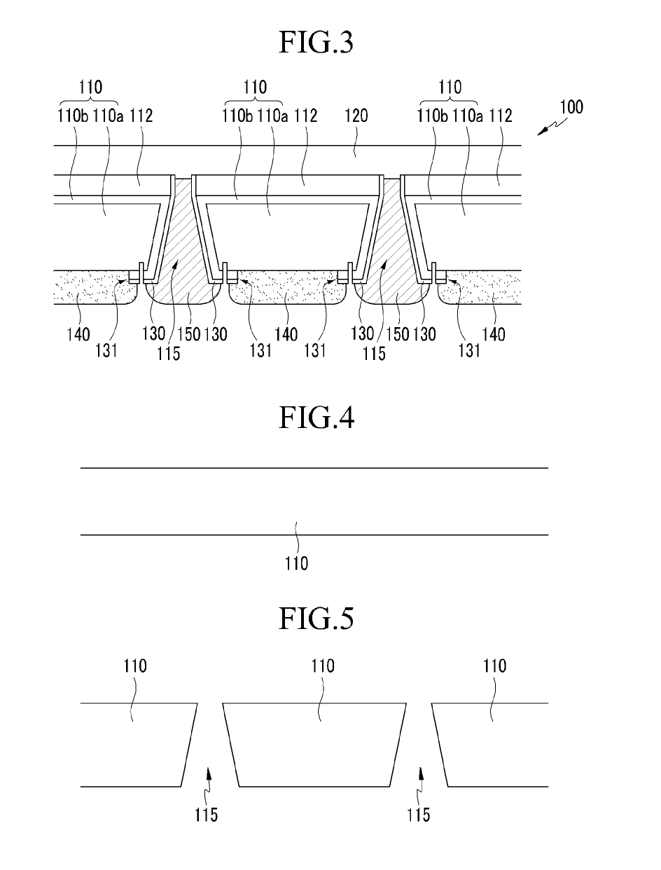

FIG. 1 is a top plan view showing the front side of an exemplary embodiment of a solar cell, FIG. 2 is a top plan view showing a rear side thereof, and FIG. 3 is a cross-sectional view of an exemplary embodiment of the solar cell taken along line III-III of FIGS. 1 and 2.

Hereinafter, the location of front and rear surfaces and top and bottom parts of a semiconductor substrate 110 are illustrated for better understanding and easier description, but the location may be different in a different view.

Referring to FIGS. 1 to 3, an exemplary embodiment of a solar cell 100 includes a semiconductor substrate 110 having a plurality of contact holes 115. Exemplary embodiments of the semiconductor substrate 110 may be formed of a crystalline silicon, a compound semiconductor, or other similar materials. Exemplary embodiments of the crystalline silicon may be formed as a silicon wafer.

The semiconductor substrate 110 includes a first semiconductor layer 110a and a second semiconductor layer 110b substantially surrounding at least a portion of the first semiconductor layer 110a, as shown in FIG. 3. One of the first and second semiconductor layers 110a and 110b is doped with a p-type impurity, and the other semiconductor layer is doped with an n-type impurity. For example, in one exemplary embodiment, the first semiconductor layer 110a may be a p-type semiconductor layer when the second semiconductor layer 110b may be an n-type semiconductor layer, and vice-versa. Herein, exemplary embodiments of the p-type impurity may include a Group III element such as boron (B) or other materials with similar characteristics, and exemplary embodiments of the n-type impurity may include a Group V element such as phosphorus (P) or other materials with similar characteristics.

The plurality of contact holes 115 pierce from a front surface to a back surface of the semiconductor substrate 110, and are arranged substantially parallel to an edge of the semiconductor substrate 110; in the exemplary embodiment illustrated in FIG. 1, the edge is the far right or left edge of the semiconductor substrate 110. In one exemplary embodiment, the contact holes 115 may have different sizes at the front and rear surfaces of the semiconductor substrate 110. For example, in one exemplary embodiment the contact holes 115 may have a truncated cone shape with a larger diameter at the rear surface than the front surface of the semiconductor substrate 110, as shown in FIG. 3. Specifically, the contact holes 115 may have a rear diameter ranging from about 30 μm to about 500 μm and a front diameter ranging from about 20 μm to about 200 μm.

When the contact holes 115 have a truncated cone shape as aforementioned, convenience and efficiency of a later-described manufacturing process may be accomplished.

However, alternative exemplary embodiments include configurations wherein the contact holes 115 may vary in arrangements, sizes, shapes, and numbers.

In one exemplary embodiment, the front surface of the semiconductor substrate 110 may be surface-textured. The surface-textured semiconductor substrate 110 may, for example, have protrusions and depressions like a pyramid, or pores like a honeycomb. The surface-textured semiconductor substrate 110 may have an enlarged surface area to enhance the light-absorption rate and decrease the reflectivity, resultantly improving efficiency of a solar cell including the same.

An insulation layer 112 is formed on the semiconductor substrate 110. In one exemplary embodiment, the insulation layer 112 may be formed of an insulating material that absorbs little light, for example, silicon nitride (SiNx), silicon oxide (SiO₂), titanium oxide (TiO₂), aluminum oxide (Al₂O₃), magnesium oxide (MgO), cerium oxide (CeO₂), a combination thereof, or other materials with similar characteristics. Exemplary embodiments include configurations wherein the insulation layer 112 may be a single layer or more than one layer. The insulation layer 112 may have a thickness ranging from about 200 Å to about 1500 Å.

The insulation layer 112 may function as an anti-reflective coating (“ARC”) that decreases the reflectivity of light and increases selectivity of a particular wavelength region on the surface of the solar cell, and simultaneously improves characteristics of silicon in the surface of the semiconductor substrate 110, resultantly increasing efficiency of the solar cell.

A plurality of front electrodes 120 are formed on the insulation layer 112. The front electrodes 120 are arranged substantially in parallel to the substrate in one direction and penetrate through the insulation layer 112 and contact the second semiconductor layer 110b. Exemplary embodiments of the front electrode 120 may be formed of a low-resistance material such as silver (Ag), aluminum (Al), or other similar materials, and may be designed to have a grid pattern wherein shadowing loss and sheet resistance are taken into consideration.

A dielectric layer 130 is disposed on the rear surface of a semiconductor substrate 110 and the side of the semiconductor substrate 110 surrounding the contact holes 115, e.g., in one exemplary embodiment the dielectric layer 130 is disposed in the contact hole 115.

The dielectric layer 130 has a contact hole 131 exposing the first semiconductor layer 110a at the rear surface of the semiconductor substrate 110, through which a rear electrode 140 may contact the semiconductor substrate 110. In the present exemplary embodiment illustrated in FIG. 3, the contact hole 131 extends through the dielectric layer 130 and the second semiconductor layer 110b.

Exemplary embodiments of the dielectric layer 130 may made of aluminum oxide (Al₂O₃), aluminum nitride (AN), aluminum oxinitride (AlON), a combination thereof or other materials with similar characteristics, and may have a thickness ranging from about 30 Å to about 1000 Å.

The exemplary embodiment of a dielectric layer 130 in FIG. 3 is shown to have a single layer, but is not limited thereto, and alternative exemplary embodiments may include two or more layers.

The dielectric layer 130 may increase efficiency of a solar cell by decreasing shunt currents and preventing recombination of carriers. In particular, when the contact holes 115 are formed in the semiconductor substrate 110, the area of the semiconductor substrate 110 around the contact holes 115 may be damaged during the contact hole 115 formation process. Charge carriers may then move across these damaged regions and form a shunt current. The carriers may be removed through recombination with metal charges of a bus bar electrode 150. The dielectric layer 130 may prevent carriers from moving toward an electrode by using fixed charges disposed thereon through the damaged part of the semiconductor substrate 110, and may thereby decrease electrical loss due to a shunt current and may also prevent a carrier loss due to recombination. Accordingly, it may decrease a leakage current and increase an open circuit voltage (“VOC”) and a fill factor (“FF”), resultantly improving solar cell efficiency.

The rear electrode 140 and the bus bar electrode 150 are separately formed under the dielectric layer 130, e.g., the dielectric layer 130 is formed to be between the bus bar electrode 150 and the semiconductor substrate 110 and between the rear electrode 140 and the substrate 110 as shown in FIG. 3. Referring to FIG. 2, in the present exemplary embodiment the bus bar electrode 150 has a horizontally and vertically extending shape, and the rear electrode 140 is disposed over substantially the entire rear surface of the semiconductor substrate 110 except for the bus bar electrode 150, but the present invention is not limited thereto.

The rear electrode 140 contacts the first semiconductor layer 110a through the contact holes 131. Exemplary embodiments of the rear electrode 140 may be made of an opaque metal such as aluminum (Al), and may have a thickness ranging from about 2 μm to about 50 μm.

Where the rear electrode 140 contacts the first semiconductor layer 110a, a metal forming the rear electrode 140, such as aluminum, contacts the first semiconductor layer 110a, exemplary embodiments of which may be made of silicon. Herein, the aluminum of the rear electrode 140 may function as a p-type impurity and forms an inner magnetic field, which prevents electrons generated from the semiconductor substrate 110 from moving toward the rear surface thereof. Therefore, carriers have a lower rate of recombination and therefore mare carriers are available at the rear surface of the semiconductor substrate 110, improving solar cell efficiency.

The bus bar electrode 150 is disposed along the direction in which a plurality of contact holes 115 are arranged in the rear surface of the semiconductor substrate 110, and is also filled in each contact hole 115. In particular, in the present exemplary embodiment the bus bar electrode 150 includes two branches extending in the direction in which the contact holes 115 are disposed, e.g., in the direction substantially perpendicular to an edge of the semiconductor substrate 110.

As described above, the dielectric layer 130 is disposed between the semiconductor substrate 110 and the bus bar electrode 150 in the contact hole 115 and blocks carriers in the semiconductor substrate 110 from moving toward the bus bar electrode 150 through the potentially damaged part of the semiconductor substrate 110, and thereby decreases a potential shunt current and prevents recombination of the carriers, resultantly increasing solar cell efficiency.

The bus bar electrode 150 is connected to the front electrode 120 through the contact holes 115, and is electrically connected to the second semiconductor layer 110b through the front electrode 120. The bus bar electrode 150 may draw out carriers generated from the second semiconductor layer 110b.

As described above, the bus bar electrode 150, which is electrically connected to the front electrode 120, is disposed on the rear surface of the semiconductor substrate 110, and decreases an area on the front surface of the semiconductor substrate 110 where metal is formed as compared to a comparative embodiment. This may decrease shadowing loss and increase solar cell efficiency as compared to a comparative embodiment wherein the bus bar electrode is formed on the front of the semiconductor substrate.

Hereinafter, an exemplary embodiment of a method of manufacturing the exemplary embodiment of a solar cell described in FIGS. 1 to 3 is illustrated referring to the accompanied drawings of FIGS. 4 to 11, as well as FIGS. 1 to 3.

FIGS. 4 to 11 are cross-sectional views sequentially showing an exemplary embodiment of a method of manufacturing an exemplary embodiment of a solar cell according to the present invention.

Referring to FIG. 4, a semiconductor substrate 110 doped with, in one exemplary embodiment, a p-type impurity is prepared.

Next, the semiconductor substrate 110 is surface-textured. Exemplary embodiments include configurations wherein the surface-texturing may be performed in a wet method using a strong acid such as nitric acid and hydrofluoric acid or a strong base such as sodium hydroxide, or in a dry method using plasma or in other suitable methods.

Referring to FIG. 5, a plurality of contact holes 115 are formed penetrating from the front surface to the rear surface of the semiconductor substrate 110. In one exemplary embodiment, the contact holes 115 may be formed using a laser, but the method is not limited thereto. As shown in the drawing, in the exemplary embodiment wherein the contact hole 115 is formed with a truncated cone shape having a larger rear diameter than front diameter, convenience and efficiency of the following processes may be increased. This will be illustrated in detail later.

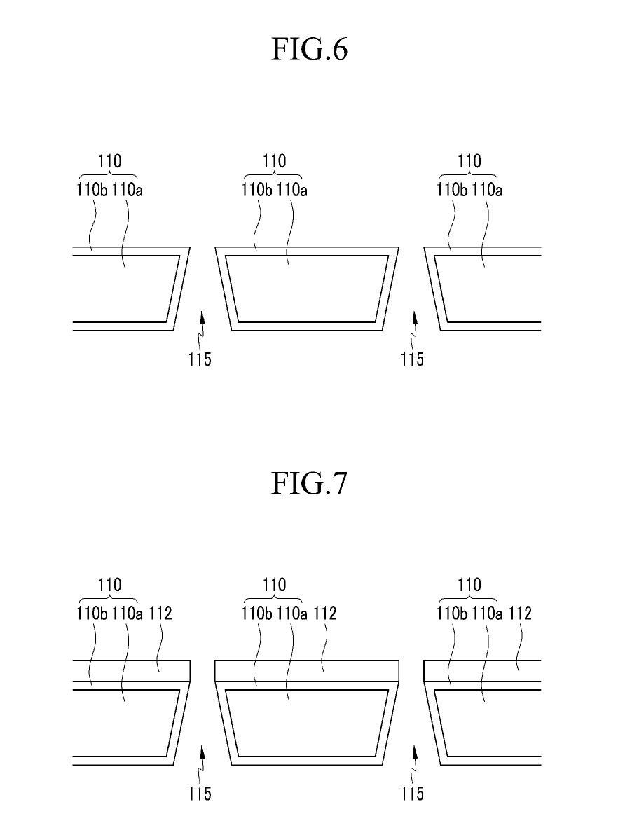

Referring to FIG. 6, the first and second semiconductor layers 110a and 110b are separately disposed to include different impurities by doping, for example, with an n-type impurity in the semiconductor substrate 110. Herein, the n-type impurity may be doped by diffusing POCl₃, H₃PO₄, or the like at a high temperature on the semiconductor substrate 110. It also may be caused to flow inside the contact hole 115 and be formed in the side of the semiconductor substrate 110, thereby substantially surrounding a p-doped first semiconductor layer 110a with an n-doped second semiconductor layer 110b.

Referring to FIG. 7, an insulation layer 112 is disposed on the front surface of the semiconductor substrate 110. In one exemplary embodiment, the insulation layer 112 may be formed by depositing silicon nitride by a plasma enhanced chemical vapor deposition (“PECVD”) method, although alternative exemplary embodiments include alternative doping methods.

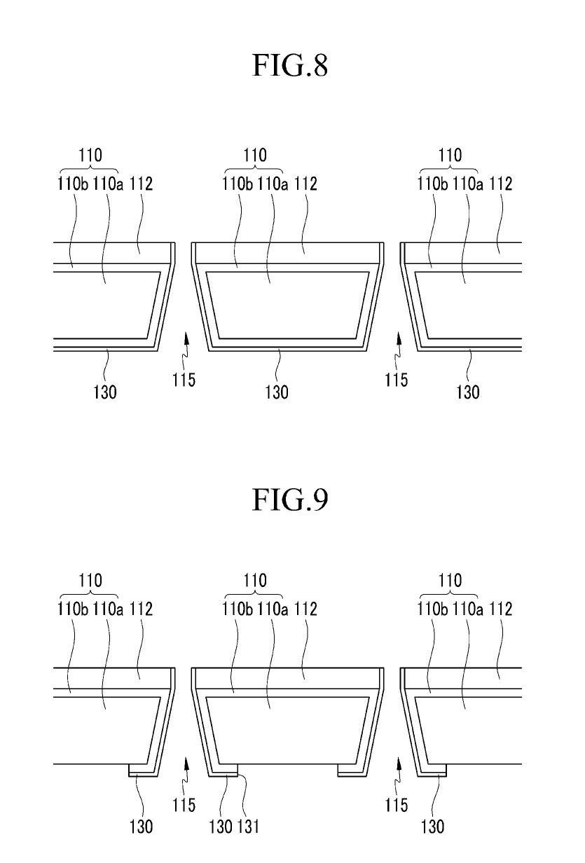

Referring to FIG. 8, a dielectric layer 130 is disposed on the rear surface and side of the semiconductor substrate 110. In one exemplary embodiment the dielectric layer 130 may be formed by an atomic layer deposition (“ALD”) method or a PECVD method. As described above, when the contact hole 115 is formed to have a truncated cone shape, it may have an entrance region having sufficient area at the rear surface of a semiconductor substrate 110 so that the dielectric layer 130 may be uniformly formed at the side of the semiconductor substrate 110 therethrough.

Referring to FIG. 9, the dielectric layer 130 on the rear surface of the semiconductor substrate 110 and a part of the second semiconductor layer 110b are removed to form a contact hole 131 exposing the first semiconductor layer 110a therethrough.

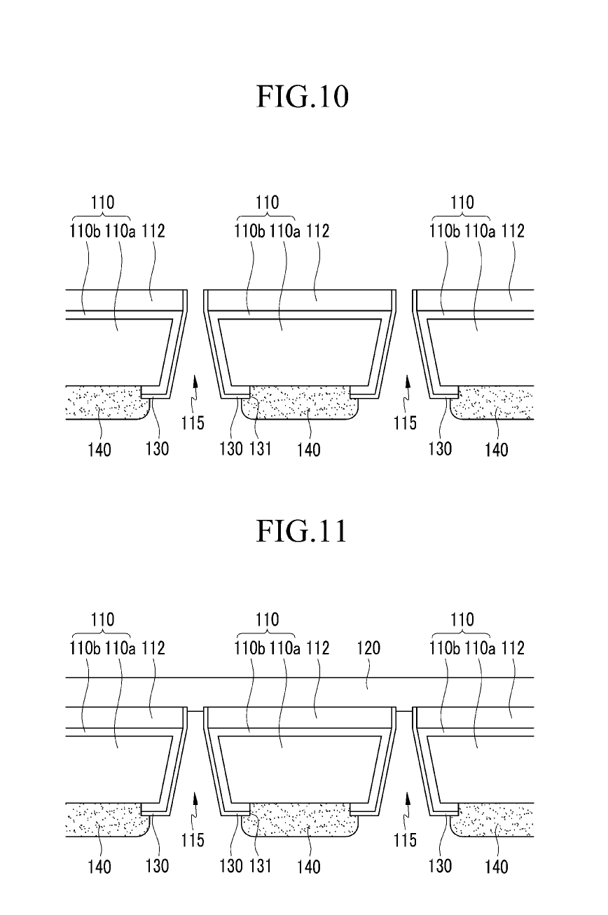

Referring to FIG. 10, a rear electrode 140 is formed under the dielectric layer 130, e.g., the rear electrode 140 is formed on the first semiconductor layer 110a and may extend beyond the contact hole 131 to cover a portion of the dielectric layer 130.

In one exemplary embodiment, the rear electrode 140 may be formed with a conductive paste including aluminum (Al) by a screen printing method, although alternative exemplary embodiments may include alternative methods of forming the rear electrode 140.

Referring to FIG. 11, a front electrode 120 is formed on the insulation layer 112. In one exemplary embodiment, the front electrode 120 may be formed with a conductive paste by a screen printing method. The screen printing method may include coating a conductive paste including metal powder such as Ag at the place where an electrode is to be formed and subsequently drying the paste. However, the present invention is not limited thereto, and alternative exemplary embodiments may include an inkjet method, imprinting, or other similar methods.

Referring to FIG. 3, a bus bar electrode 150 is formed on the contact hole 115. Exemplary embodiments include configurations wherein the bus bar electrode 150 may be formed by screen-printing a conductive paste including silver (Ag) and filling the contact hole 115 from the rear surface of the semiconductor substrate 110. As aforementioned, in the present exemplary embodiment the contact hole 115 has a larger diameter on the rear surface of the semiconductor substrate 110 than on the front surface thereof, so that it may be easily filled with a conductive paste.

Next, in the present exemplary embodiment the front electrode 120, the rear electrode 140, and the bus bar electrode 150 are co-fired in a high temperature furnace. In such an exemplary embodiment, the firing may be performed at a higher temperature than the fusion temperature of metals making up the front electrode 120, the rear electrode 140, and the bus bar electrode 150, for example at a temperature ranging from about 600° C. to about 1000° C. However, when the front electrode 120, the rear electrode 140, and the bus bar electrode 150 are formed of different conductive pastes, they may be respectively fired depending on the firing temperature of each conductive paste. For example, in one exemplary embodiment the front and rear electrodes 120 and 140 may be primarily fired, and then the bus bar electrode 150 may be secondarily fired.

Then, a part of the semiconductor substrate 110 positioned between the rear electrode 140 and the bus bar electrode 150 may be electrically isolated, e.g., by using a laser to remove a portion of the dielectric layer 130 and the second semiconductor layer 110b between the rear electrode 140 and the bus bar electrode 150 as shown in FIG. 3.

In the exemplary embodiment described above, the electrodes are formed in an order of the rear electrode 140, the front electrode 120, and the bus bar electrode 150, but the present invention is not limited thereto, and may be formed in the opposite order of the front electrode 120 and then the rear electrode 140, or in various other orders in order to achieve the structure illustrated in FIG. 3.

Hereinafter, another exemplary embodiment of a solar cell is illustrated referring to FIG. 12 and FIGS. 1 and 2.

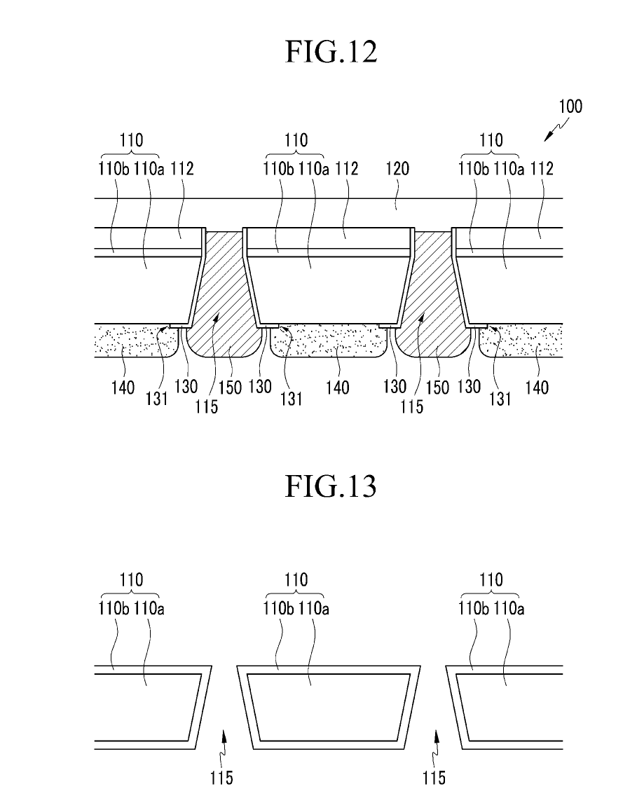

FIG. 12 shows a cross-sectional view of an exemplary embodiment of a solar cell taken along line III-III of FIGS. 1 and 2.

Hereinafter, repeated descriptions will be omitted, and the aforementioned reference numerals indicate the same constituent elements.

Referring to FIG. 12, a semiconductor substrate 110 includes first and second semiconductor layer 110a and 110b doped with different conductive type impurities, and a plurality of contact holes 115 penetrating the semiconductor substrate 110 from front to back.

An insulation layer 112 is formed on the front surface of the semiconductor substrate 110 and plurality of front electrodes 120 are disposed thereon.

The second semiconductor layer 110b is removed on the rear surface of the semiconductor substrate 110 and its side surrounding the contact hole 115. When the contact holes 115 are formed using a laser, the second semiconductor layer 110b may potentially be damaged by a laser and a shunt current may potentially be formed. However, in the present exemplary embodiment, the second semiconductor layer 110b surrounding the contact hole 115 is removed in advance, thereby preventing carrier loss through a shunt current. A dielectric layer 130 is formed on the rear surface of the semiconductor substrate 110 and its side surrounding the contact hole 115. However, the dielectric layer 130 directly contacts the first semiconductor layer 110a, unlike the aforementioned exemplary embodiment.

The dielectric layer 130 has contact holes 131 exposing the first semiconductor layer 110a on the rear surface of the semiconductor substrate 110.

A rear electrode 140 and a bus bar electrode 150 are separately disposed under, e.g., below, the dielectric layer 130 as seen from a cross-sectional view. The rear electrode 140 contacts the first semiconductor layer 110a through the contact holes 131. The bus bar electrode 150 is filled in the contact holes 115 and connected to a front electrode 120 through the contact holes 115.

Hereinafter, an exemplary embodiment of a method of manufacturing an exemplary embodiment of a solar cell of FIG. 12 is illustrated referring to FIGS. 13 to 19.

FIGS. 13 to 19 are cross-sectional views sequentially showing another exemplary embodiment of a method of manufacturing an exemplary embodiment of a solar cell.

Referring to FIG. 13, a plurality of contact holes 115 are formed to penetrate from the front to the rear surface of a semiconductor substrate 110 doped with, for example, a p-type impurity, and the semiconductor substrate 110 is doped with, for example, a n-type impurity to differentiate the second semiconductor layer 110b from the first semiconductor layer 110a, similar to the exemplary embodiment illustrated in FIG. 6.

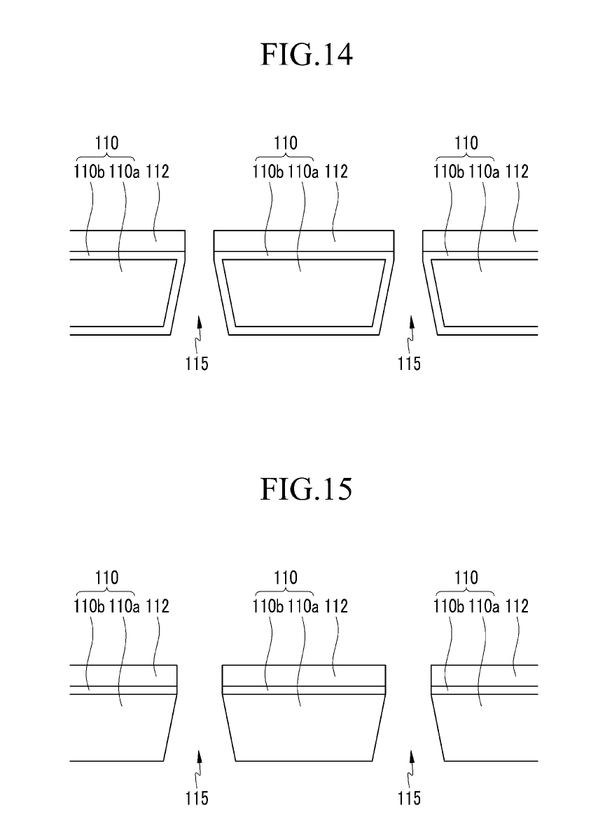

Referring to FIG. 14, an insulation layer 112 is disposed on the front surface of the semiconductor substrate 110, similar to the exemplary embodiment illustrated in FIG. 7.

Referring to FIG. 15, the insulation layer 112 is used as a mask to etch the second semiconductor layer 110b. Herein, exemplary embodiments of the etching may be a dry method or a wet method. Accordingly, the second semiconductor layer 110b remains between the first semiconductor layer 110a and the insulation layer 112, but is otherwise removed from the semiconductor substrate 110. Specifically, the second semiconductor layer 110b positioned at the rear surface and the side of the semiconductor substrate 110 is removed.

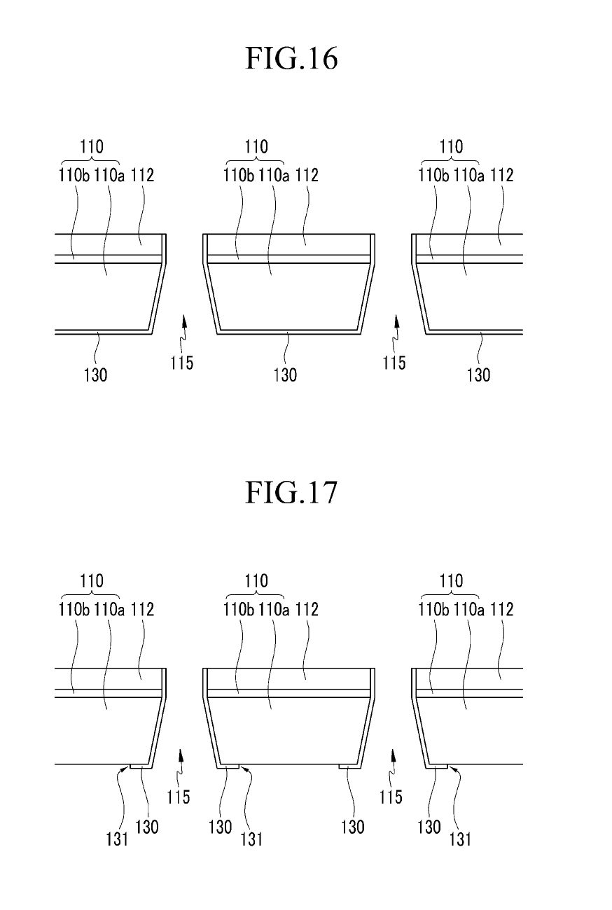

Referring to FIG. 16, a dielectric layer 130 is disposed on the rear surface and the side of the semiconductor substrate 110. Unlike the aforementioned exemplary embodiments, since the second semiconductor layer 110b is removed at the rear surface and the side of the semiconductor substrate 110, the dielectric layer 130 is directly disposed on the first semiconductor layer 110a.

Referring to FIG. 17, contact holes 131 are formed to expose the first semiconductor layer 110a by removing a part of the dielectric layer 130 on the rear surface of the semiconductor substrate 110.

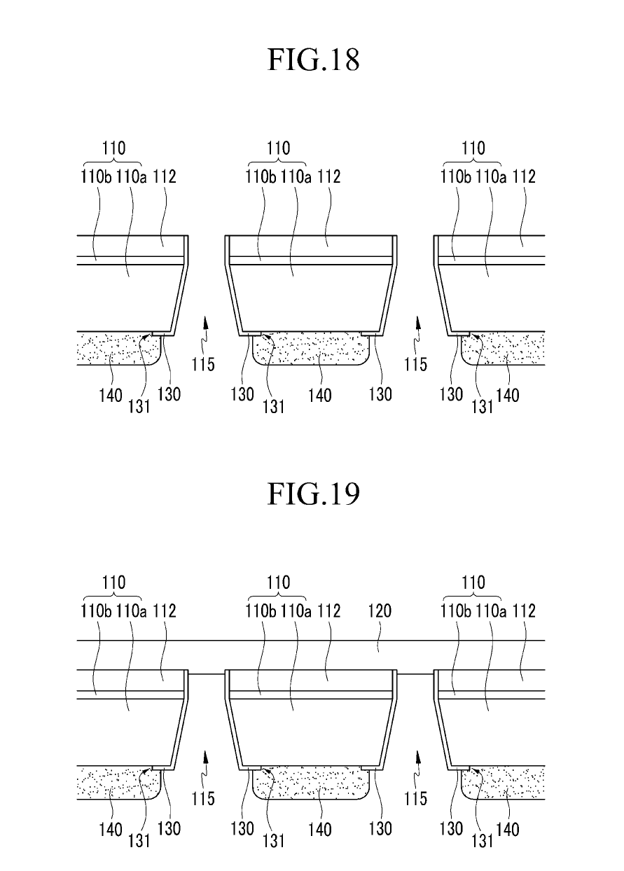

Referring to FIG. 18, a rear electrode 140 is disposed under the dielectric layer 130, e.g., below the dielectric layer 130 as seen from a cross-sectional view. In one exemplary embodiment, the rear electrode 140 is formed with a conductive paste including aluminum (Al) by a screen-printing method.

Referring to FIG. 19, a front electrode 120 is disposed on an insulation layer 112. In one exemplary embodiment, the front electrode 120 is formed with a conductive paste including a metal powder such as silver (Ag) and the like by a screen-printing method, although alternative exemplary embodiments include configurations wherein the front electrode 120 is formed by alternative methods.

Referring to FIG. 12, a bus bar electrode 150 is formed in the contact holes 115. In one exemplary embodiment, the bus bar electrode 150 is formed by filling a conductive paste in the contact holes 115 by a screen-printing method.

Next, the front electrode 120, the rear electrode 140, and the bus bar electrode 150 are fired.

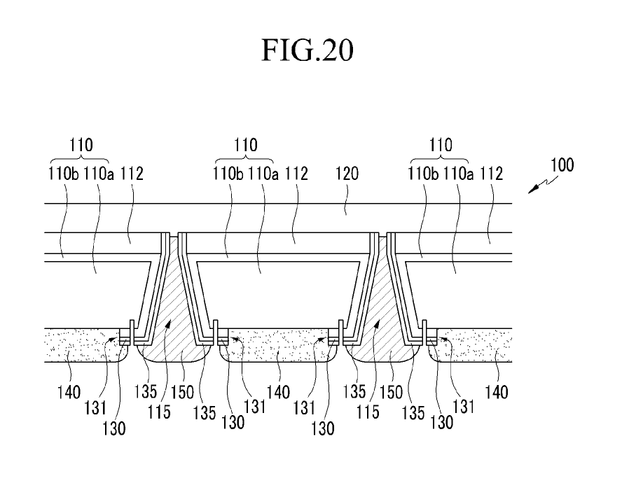

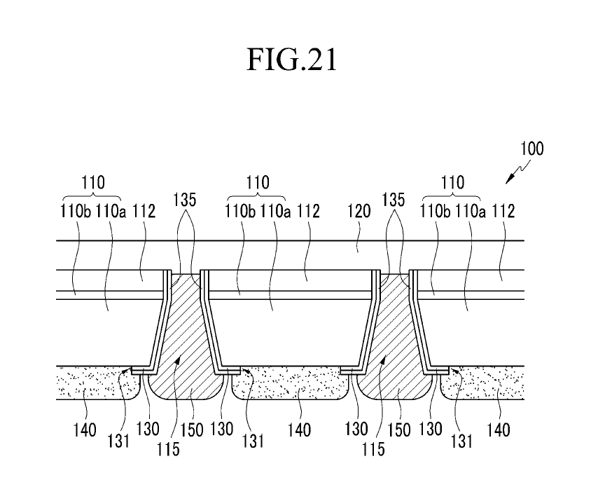

Hereinafter, another exemplary embodiment of a solar cell is illustrated referring to the accompanied drawings FIGS. 20 and 21 as well as FIGS. 1 and 2.

FIGS. 20 and 21 are respectively cross-sectional views of additional exemplary embodiment of a solar cell. FIG. 20 illustrates an exemplary embodiment similar to the exemplary embodiment described with respect to FIG. 3, and FIG. 21 illustrates an exemplary embodiment similar to the exemplary embodiment described with respect to FIG. 12.

As shown in FIGS. 20 and 21, a current exemplary embodiment of a solar cell includes a protective layer 135 disposed on a dielectric layer 130, unlike the first and second exemplary embodiments. The protective layer 135 is formed of an insulating material such as silicon oxide (SiO₂), silicon nitride (SiNₓ), or other materials with similar characteristics. The protective layer 135 may protect the dielectric layer 130 from damage during formation of the contact holes 115 and the rear electrode 140, and simultaneously enhances its adherence to a conductive paste during formation of a rear electrode 140, so that the rear electrode 140 may not be lifted or peeled off.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a semiconductor substrate comprising:
a first conductive type part including one of a p-type material and an n-type material;
a second conductive type part including the other of a p-type material and an n-type material different from the first conductive type part; and
a plurality of contact holes which penetrate from a first surface of the semiconductor substrate to a second surface thereof, wherein the first surface and the second surface are substantially opposite to one another;
a first electrode disposed on the first surface of the semiconductor substrate and electrically connected to the second conductive type part of the semiconductor substrate;
a second electrode disposed on the second surface of the semiconductor substrate and electrically connected to the first conductive type part of the semiconductor substrate; and
a dielectric layer disposed between the semiconductor substrate and the second electrode in the plurality of contact holes.

2. The solar cell of claim 1, further comprising a plurality of third electrodes disposed on a surface of the semiconductor substrate corresponding to the plurality of contact holes, respectively, wherein the plurality of third electrodes are electrically connected to the first electrode through the plurality of contact holes.

3. The solar cell of claim 2, wherein the plurality of the third electrodes are arranged adjacent to one another along a first direction.

4. The solar cell of claim 3, wherein a plurality of the plurality of contact holes are arranged in a direction substantially perpendicular to the first direction.

5. The solar cell of claim 2, further comprising an insulation layer disposed between the semiconductor substrate and the first electrode.

6. The solar cell of claim 1, wherein the dielectric layer is disposed between the first conductive type part of the semiconductor substrate and the plurality of third electrodes in the plurality of contact holes.

7. The solar cell of claim 1, wherein the dielectric layer is disposed between the second conductive type part of the semiconductor substrate and the third electrode in the plurality of contact holes.

8. The solar cell of claim 1, wherein the second electrode fills at least a portion of a dielectric contact hole disposed in the dielectric layer on the second surface of the semiconductor substrate.

9. The solar cell of claim 1, wherein the dielectric layer surrounds the plurality of contact holes.

10. The solar cell of claim 9, wherein the dielectric layer comprises at least one material selected from the group consisting of Al₂O₃, AN, AlON, and a combination thereof.

11. The solar cell of claim 1, wherein the plurality of contact holes have a different diameter at the first surface of the semiconductor substrate and the second surface of the semiconductor substrate.

12. The solar cell of claim 11, wherein the contact holes have a truncated cone shape.

13. The solar cell of claim 1, further comprising a protective layer disposed on the dielectric layer.

14. A method of manufacturing a solar cell comprising:
preparing a first conductive type part of a semiconductor substrate, wherein the first conductive type part is selected from one of a p-type material and an n-type material;
forming a plurality of contact holes extending from a first surface of the semiconductor substrate to a second surface of the semiconductor substrate;
preparing a second conductive type part, including the other of a p-type material and an n-type material different than the first conductive type part, by providing a part of the semiconductor substrate with impurities;
disposing a dielectric layer on the second surface and a side of the semiconductor substrate corresponding to the plurality of contact holes;
disposing a first electrode electrically connected to the second conductive type part of the semiconductor substrate on the first surface of the semiconductor substrate; and
disposing a second electrode electrically connected to the first conductive type part of the semiconductor substrate on the second surface thereof, wherein the second electrode is separated from the first electrode.

15. The method of claim 14, further comprising connecting a plurality of third electrodes to the first electrode on the first surface of the semiconductor substrate.

16. The method of claim 15, wherein at least one of the first electrode, the second electrode, and the plurality of third electrodes is disposed on the semiconductor substrate by a screen-printing method.

17. The method of claim 14, further comprising disposing an insulation layer on the first surface of the semiconductor substrate after supplying the second conductive type part of the semiconductor substrate with impurities.

18. The method of claim 17, further comprising removing the second conductive type part before disposing a dielectric layer on the second surface and the side of the semiconductor substrate corresponding to the plurality of contact holes.

19. The method of claim 18, wherein the second conductive type part is removed using the insulation layer as a mask.

20. The method of claim 14, further comprising disposing a protective layer on the semiconductor substrate after disposing the dielectric layer on the first surface and the side of the semiconductor substrate corresponding to the plurality of contact holes.
